(19) United States
(12) Patent Application Publication
(10) Pub. No.: US 2023/0317671 A1
(43) Pub. Date: Oct. 5, 2023

(54) SUBSTRATE TRENCH FOR CONTROLLING UNDERFILL FILLET AREA AND METHODS OF FORMING THE SAME

(71) Applicant: Taiwan Semiconductor Manufacturing Company Limited, Hsinchu (TW)

(72) Inventors: Chia-Kuei Hsu, Hsinchu City (TW); Ming-Chih Yew, Hsinchu City (TW); Li-Ling Liao, Hsinchu City (TW); Shin-Puu Jeng, Po-Shan Village (TW)

(21) Appl. No.: 17/708,348

(22) Filed: Mar. 30, 2022

(51) Int. Cl. H01L 23/00; H01L 23/498

(52) U.S. Cl. CPC H01L 24/32; H01L 23/49816; H01L 2924/15172; H01L 2924/3512; H01L 2924/3511; H01L 2924/1437; H01L 25/0652

(57) ABSTRACT

A semiconductor structure and methods for forming the same including a package comprising at least one semiconductor die, a redistribution structure comprising bonding pads, and a first underfill material portion located between the at least one semiconductor die and the redistribution structure, a substrate package comprising chip-side bonding pads and at least one substrate trench, in which the at least one substrate trench extends vertically below a top surface of the substrate package in a cross-section view, solder material portions bonded to the chip-side bonding pads and the bonding pads, and a second underfill material portion laterally surrounding the solder material portions and dispensed within the at least one substrate trench.

### BACKGROUND

Interfaces between a fan-out wafer level package (FOWLP) and an underfill material portion are subjected to mechanical stress during subsequent handling of an assembly of the FOWLP, the underfill material portion, and a packaging substrate, such as the mechanical stress associated with attaching the substrate package to a printed circuit board (PCB). In addition, interfaces between a FOWLP and an underfill material portion are subjected to mechanical stress during use within a computing device, such as when a mobile device is accidently dropped to cause a mechanical shock during usage. Cracks may be formed in the underfill material, and may induce additional cracks in a semiconductor die, solder material portions, redistribution structures, and/or various dielectric layers within a semiconductor die or within a packaging substrate. Thus, suppression of the formation of cracks in the underfill material is desired.

A wide underfill material portion surrounding the FOWLP and extending outward from the FOWLP across a package substrate may further increase the risk of additional cracks in the underfill material, semiconductor die, solder material portions, redistribution structures, and/or various dielectric layers within a semiconductor die or within a packaging substrate. For example, a wider underfill material portion may induce greater mechanical stress on the FOWLP and the interfaces between a FOWLP and the underfill material than the mechanical stress exerted by a narrower underfill material portion. This may result from a wider underfill portion having a larger contact surface area across the substrate package than a less wide, or narrower, underfill portion, in which the wider underfill portion may experience greater deformation during the event of a deformation or bending of the package substrate during operation as one example. In other words, the larger the contact surface area of the underfill material to the package substrate, the greater the risk of underfill material deformation due to substrate package deformation, and in turn, the greater the mechanical stress on the FOWLP and corresponding interface structures. Thus, reduction of the total width of the underfill material (i.e., reduction of the spread of the underfill material outward from the FOWLP across the substrate package during the underfill dispensing procedure) is desired to (i) further suppress the formation of cracks in the underfill material and/or (ii) increase the available surface area across the substrate package for placement of additional components.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a vertical cross-sectional view of a region of an exemplary structure that includes a first carrier substrate and redistribution structures according to an embodiment of the present disclosure.

FIG. 1B is a top-down view of the region of the exemplary structure of FIG. 1A.

FIG. 2A is vertical cross-sectional view of a region of the exemplary structure after formation of redistribution-side bonding structures and first solder material portions according to an embodiment of the present disclosure.

FIG. 2B is a top-down view of the region of the exemplary structure of FIG. 2A.

FIG. 3A is a vertical cross-sectional view of a region the exemplary structure after attaching semiconductor dies according to an embodiment of the present disclosure.

FIG. 3B is a top-down view of the region of the exemplary structure of FIG. 3A.

FIG. 3C is a magnified vertical cross-sectional view of a high bandwidth memory die.

FIG. 4 is a vertical cross-sectional view of a region of the exemplary structure after formation of first underfill material portions.

FIG. 5A is a vertical cross-sectional view of a region of the exemplary structure after formation of an epoxy molding compound (EMC) matrix according to an embodiment of the present disclosure.

FIG. 5B is a top-down view of the region of the exemplary structure of FIG. 5A.

FIG. 6 is a vertical cross-sectional view of a region of the exemplary structure after attaching a second carrier substrate and detaching the first carrier substrate according to an embodiment of the present disclosure.

FIG. 7 is a vertical cross-sectional view of a region of the exemplary structure after formation of fan-out bonding pads according to an embodiment of the present disclosure.

FIG. 8 is a vertical cross-sectional view of a region of the exemplary structure after detaching the second carrier substrate according to an embodiment of the present disclosure.

FIG. 9 is a vertical cross-sectional view of a region of the exemplary structure during dicing of a redistribution substrate and the EMC matrix according to an embodiment of the present disclosure.

FIG. 10A is a vertical cross-sectional view of a fan-out package according to an embodiment of the present disclosure.

FIG. 10B is a horizontal cross-sectional view of the fan-out package along the horizontal plane B-B′ of FIG. 10A.

FIG. 11 is a vertical cross-sectional view of a substrate package according to an embodiment of the present disclosure.

FIG. 12A is a vertical cross-sectional view of the substrate package after formation of a substrate trench according to an embodiment of the present disclosure.

FIG. 12B is a top-down view of the substrate package of FIG. 12A.

FIG. 13 is a vertical cross-sectional view of an exemplary structure after attaching the fan-out package to the substrate package according to an embodiment of the present disclosure.

FIG. 14A is a vertical cross-sectional view of the exemplary structure after formation of a second underfill material portion according to an embodiment of the present disclosure.

FIG. 14B is a horizontal cross-sectional view of the exemplary structure along the horizontal plane B-B′ of FIG. 14A.

FIG. 14C is a magnified vertical cross-sectional view of a region of the exemplary structure of FIG. 14A.

FIG. 15 is a magnified vertical cross-sectional view of a first alternative embodiment of a region of the exemplary structure of FIG. 14A.

FIG. 16 is a vertical cross-sectional view of a second alternative embodiment of the exemplary structure of FIG. 12A.

FIG. 17 is a vertical cross-sectional view of the second alternative embodiment of the exemplary structure of FIG. 14A.

FIG. 18 is a vertical cross-sectional view of a third alternative embodiment of the exemplary structure of FIG. 12A.

FIG. 19A is a horizontal cross-sectional view of a third alternative embodiment of the exemplary structure along a horizontal plane that corresponds to the horizontal plane B-B′ of FIG. 14A.

FIG. 19B is a horizontal cross-sectional view of a fourth alternative embodiment of the exemplary structure along a horizontal plane that corresponds to the horizontal plane B-B′ of FIG. 14A.

FIG. 19C is a horizontal cross-sectional view of a fifth alternative embodiment of the exemplary structure along a horizontal plane that corresponds to the horizontal plane B-B′ of FIG. 14A.

FIG. 20 is a vertical cross-sectional view of the exemplary structure after the substrate package is attached to a printed circuit board (PCB) according to an embodiment of the present disclosure.

FIG. 21 is a flowchart illustrating steps for forming an exemplary structure according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

The present disclosure is directed to semiconductor devices, and particularly to uniform application of an underfill material in semiconductor die packaging. Generally, the methods and structures of the present disclosure may be used to provide a chip package structure such as a FOWLP and fan-out panel level package (FOPLP). While the present disclosure is described using an FOWLP configuration, the methods and structures of the present disclosure may be implemented in an FOPLP configuration or any other fan-out package configuration.

Fan-out packages are subject to deformation under stress during subsequent assembly processes and/or during operation under mechanical stress and/or under heat. Overflow and extension of underfill material outward from a fan-out package and between a fan-out package and a substrate package may also contribute to the total mechanical stress exerted on the fan-out package during deformation or bending of the substrate package. Excess underfill material that extends outward from the sidewalls of the fan-out package also reduces the board space that would otherwise be available to place additional components, such as surface-mount devices (SMDs) and board stiffeners that would help reduce the mechanical stress of the overall semiconductor device.

According to an aspect of the present disclosure, deformation of a fan-out package and fillet width of an underfill material may be reduced by using at least one substrate trench formed into the substrate package. The at least one substrate trench may be etched or drilled (such as through computer numerical control (CNC) milling) into one or more layers of the substrate package to create a volume of space usable as a repository for underfill material. Underfill material may be displaced into the volume of the substrate trench, allowing less underfill material to extend, or spill, outward from the sidewalls of the fan-out package. Thus, by creating a substrate trench to hold volumes of underfill material that would otherwise extend onto a surface of the substrate package, the fillet width of the underfill material may be reduced, and more board space may be made available for additional components. The various aspects and embodiments of the methods and structures of the present disclosure are described with reference to accompanying drawings here below.

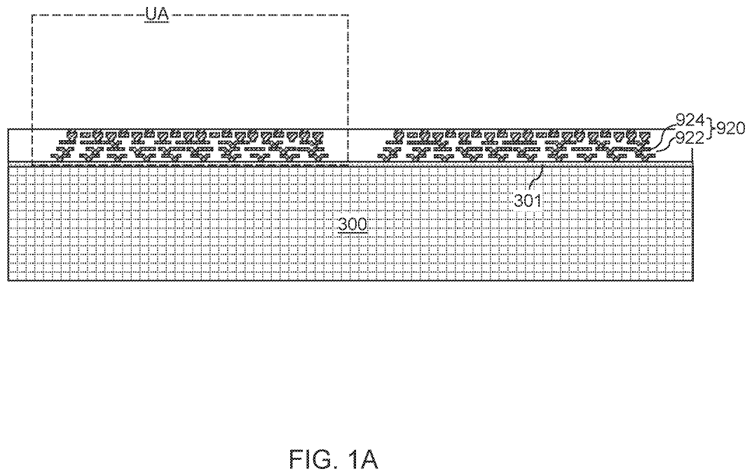

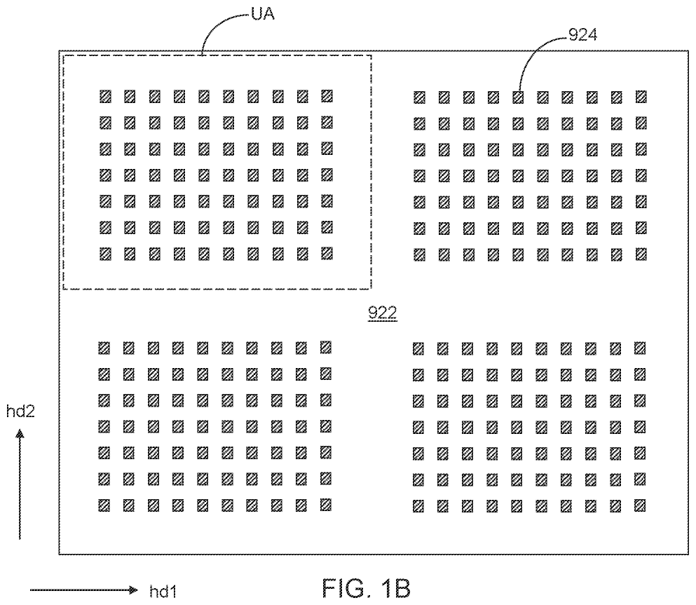

Referring to FIGS. 1A and 1B, an exemplary structure according to an embodiment of the present disclosure may include a first carrier substrate 300 and redistribution structures 920 formed on a front side surface of the first carrier substrate 300. The first carrier substrate 300 may include an optically transparent substrate such as a glass substrate or a sapphire substrate. The diameter of the first carrier substrate 300 may be in a range from 150 mm to 290 mm, although lesser and greater diameters may be used. In addition, the thickness of the first carrier substrate 300 may be in a range from 500 microns to 2,000 microns, although lesser and greater thicknesses may also be used. Alternatively, the first carrier substrate 300 may be provided in a rectangular panel format. The dimensions of the first carrier in such alternative embodiments may be substantially the same.

A first adhesive layer 301 may be applied to the front-side surface of the first carrier substrate 300. In one embodiment, the first adhesive layer 301 may be a light-to-heat conversion (LTHC) layer. The LTHC layer may be a solvent-based coating applied using a spin coating method. The LTHC layer may convert ultraviolet light to heat, which may cause the material of the LTHC layer to lose adhesion. Alternatively, the first adhesive layer 301 may include a thermally decomposing adhesive material. For example, the first adhesive layer 301 may include an acrylic pressure-sensitive adhesive that decomposes at an elevated temperature. The debonding temperature of the thermally decomposing adhesive material may be in a range from 150 degrees to 200 degrees Celsius.

Redistribution structures 920 may be formed over the first adhesive layer 301. Specifically, a redistribution structure 920 may be formed within each unit area UA, which is the area of a repetition unit that may be repeated in a two-dimensional array over the first carrier substrate 300. Each redistribution structure 920 may include redistribution dielectric layers 922 and redistribution wiring interconnects 924. The redistribution dielectric layers 922 include a respective dielectric polymer material such as polyimide (PI), benzocyclobutene (BCB), or polybenzobisoxazole (PBO). Other suitable materials may be within the contemplated scope of disclosure. Each redistribution dielectric layer 922 may be formed by spin coating and drying of the respective dielectric polymer material. The thickness of each redistribution dielectric layer 922 may be in a range from 2 microns to 40 microns, such as from 4 microns to 20 microns. Each redistribution dielectric layer 922 may be patterned, for example, by applying and patterning a respective photoresist layer thereabove, and by transferring the pattern in the photoresist layer into the redistribution dielectric layer 922 using an etch process such as an anisotropic etch process. The photoresist layer may be subsequently removed, for example, by ashing.

Each of the redistribution wiring interconnects 924 may be formed by depositing a metallic seed layer by sputtering, by applying and patterning a photoresist layer over the metallic seed layer to form a pattern of openings through the photoresist layer, by electroplating a metallic fill material (such as copper, nickel, or a stack of copper and nickel), by removing the photoresist layer (for example, by ashing), and by etching portions of the metallic seed layer located between the electroplated metallic fill material portions. The metallic seed layer may include, for example, a stack of a titanium barrier layer and a copper seed layer. The titanium barrier layer may have thickness in a range from 50 nm to 400 nm, and the copper seed layer may have a thickness in a range from 100 nm to 500 nm. The metallic fill material for the redistribution wiring interconnects 924 may include copper, nickel, or copper and nickel. Other suitable metallic fill materials are within the contemplated scope of disclosure. The thickness of the metallic fill material that is deposited for each redistribution wiring interconnect 924 may be in a range from 2 microns to 40 microns, such as from 4 microns to 10 microns, although lesser or greater thicknesses may also be used. The total number of levels of wiring in each redistribution structure 920 (i.e., the levels of the redistribution wiring interconnects 924) may be in a range from 1 to 10. A periodic two-dimensional array (such as a rectangular array) of redistribution structures 920 may be formed over the first carrier substrate 300. Each redistribution structure 920 may be formed within a unit area UA. The layer including all redistribution structures 920 is herein referred to as a redistribution structure layer, and is not limited thereto. The redistribution structure layer includes a two-dimensional array of redistribution structures 920. In one embodiment, the two-dimensional array of redistribution structures 920 may be a rectangular periodic two-dimensional array of redistribution structures 920 having a first periodicity along a first horizontal direction hd1 and having a second periodicity along a second horizontal direction hd2 that is perpendicular to the first horizontal direction hd1.

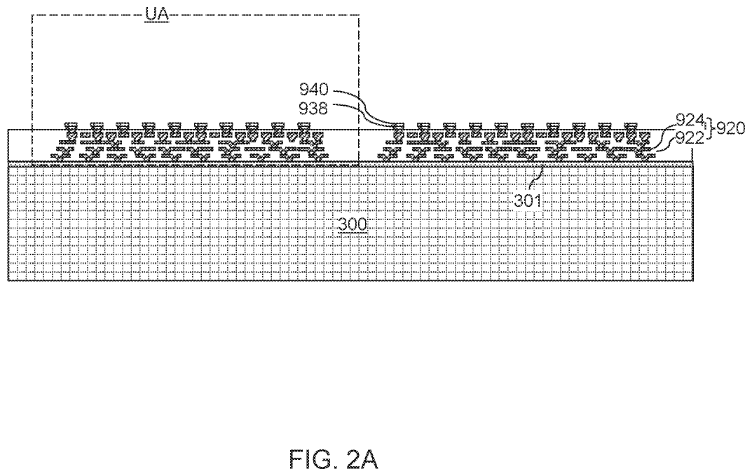

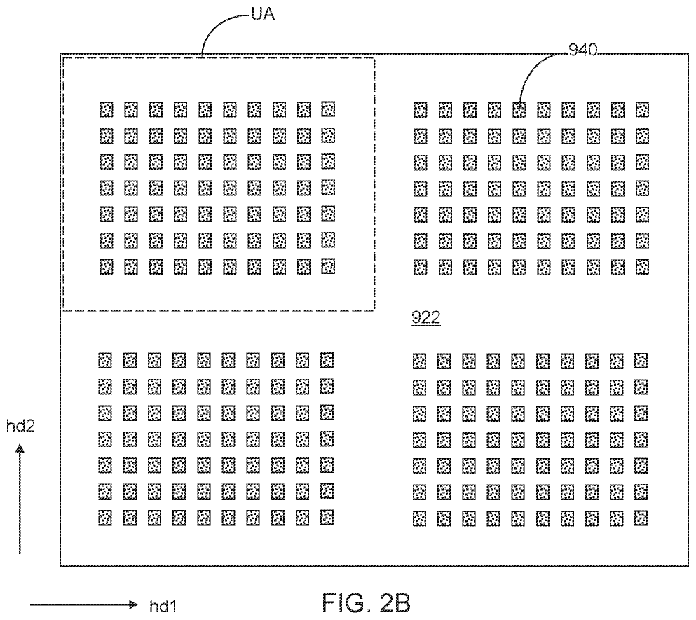

Referring to FIGS. 2A and 2B, at least one metallic material and a first solder material may be sequentially deposited over the front-side surface of the redistribution structures 920. The at least one metallic material comprises a material that may be used for metallic bumps, such as copper. The thickness of the at least one metallic material may be in a range from 5 microns to 60 microns, such as from 10 microns to 30 microns, although lesser and greater thicknesses may also be used. The first solder material may comprise a solder material suitable for C2 bonding, i.e., for microbump bonding. The thickness of the first solder material may be in a range from 2 microns to 30 microns, such as from 4 microns to 15 microns, although lesser and greater thicknesses may also be used.

The first solder material and the at least one metallic material may be patterned into discrete arrays of first solder material portions 940 and arrays of metal bonding structures, which are herein referred to as arrays of redistribution-side bonding structures 938. Each array of redistribution-side bonding structures 938 is formed within a respective unit area UA. Each array of first solder material portions 940 is formed within a respective unit area UA. Each first solder material portion 940 may have a same horizontal cross-sectional shape as an underlying redistribution-side bonding structures 938.

In one embodiment, the redistribution-side bonding structures 938 may include, and/or may consist essentially of, copper or a copper-containing alloy. Other suitable materials are within the contemplated scope of disclosure. The thickness of the redistribution-side bonding structures 938 may be in a range from 5 microns to 60 microns, although lesser or greater thicknesses may also be used. The redistribution-side bonding structures 938 may have horizontal cross-sectional shapes of rectangles, rounded rectangles, circles, regular polygons, irregular polygons, or any other two-dimensional curvilinear shape having a closed periphery. In one embodiment, redistribution-side bonding structures 938 may be configured for microbump bonding (i.e., C2 bonding), and may have a thickness in a range from 10 microns to 30 microns, although lesser or greater thicknesses may also be used. In this embodiment, each array of redistribution-side bonding structures 938 may be formed as an array of microbumps (such as copper pillars) having a lateral dimension in a range from 10 microns to 25 microns, and having a pitch in a range from 20 microns to 50 microns.

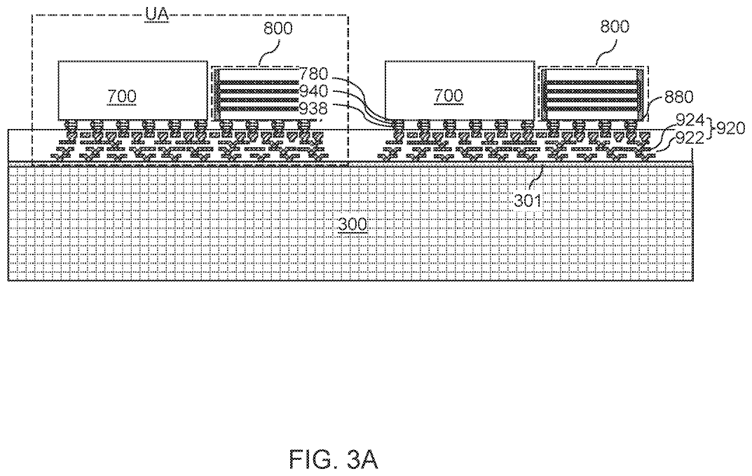

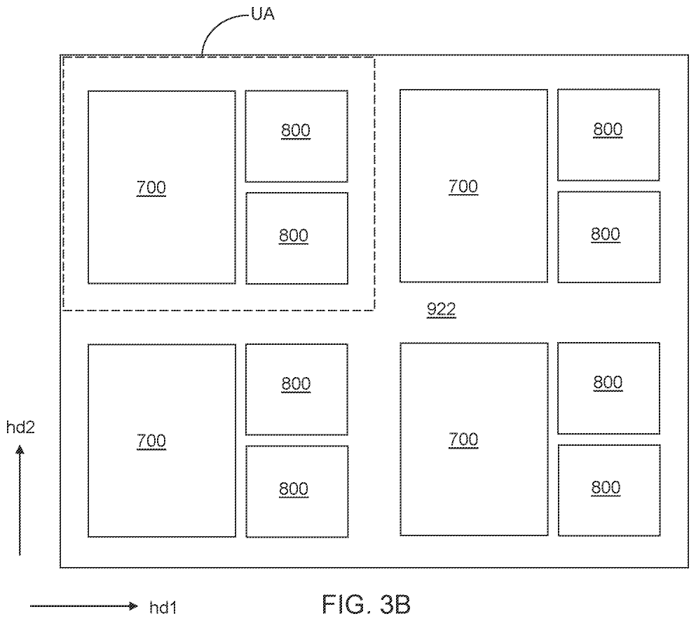

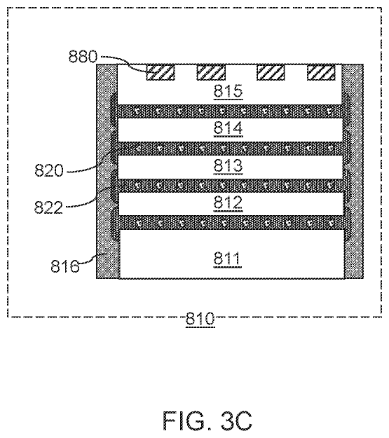

Referring to FIGS. 3A and 3B, a set of at least one semiconductor die (700, 800) may be bonded to each redistribution structure 920. In one embodiment, the redistribution structures 920 may be arranged as a two-dimensional periodic array, and multiple sets of at least one semiconductor die (700, 800) may be bonded to the redistribution structures 920 as a two-dimensional periodic rectangular array of sets of the at least one semiconductor die (700, 800). Each set of at least one semiconductor die (700, 800) includes at least one semiconductor die. Each set of at least one semiconductor die (700, 800) may include any set of at least one semiconductor die known in the art. In one embodiment, each set of at least one semiconductor die (700, 800) may comprise a plurality of semiconductor dies (700, 800). For example, each set of at least one semiconductor die (700, 800) may include at least one system-on-chip (SoC) die 700 and/or at least one memory die 800. Each SoC die 700 may comprise an application processor die, a central processing unit die, or a graphic processing unit die. In one embodiment, the at least one memory die 800 may comprise a high bandwidth memory (HBM) die that includes a vertical stack of static random-access memory dies. In one embodiment, the at least one semiconductor die (700, 800) may include at least one system-on-chip (SoC) die and a high bandwidth memory (HBM) die including a vertical stack of static random-access memory (SRAM) dies that are interconnected to one another through microbumps and are laterally surrounded by an epoxy molding material enclosure frame.

Each semiconductor die (700, 800) may comprise a respective array of die-side bonding structures (780, 880). For example, each SoC die 700 may comprise an array of SoC metal bonding structures 780, and each memory die 800 may comprise an array of memory-die metal bonding structures 880. Each of the semiconductor dies (700, 800) may be positioned in a face-down position such that die-side bonding structures (780, 880) face the first solder material portions 940. Each set of at least one semiconductor die (700, 800) may be placed within a respective unit area UA. Placement of the semiconductor dies (700, 800) may be performed using a pick and place apparatus such that each of the die-side bonding structures (780, 880) may be placed on a top surface of a respective one of the first solder material portions 940.

Generally, a redistribution structure 920 including redistribution-side bonding structures 938 thereupon may be provided, and at least one semiconductor die (700, 800) including a respective set of die-side bonding structures (780, 880) may be provided. The at least one semiconductor die (700, 800) may be bonded to the redistribution structure 920 using first solder material portions 940 that are bonded to a respective redistribution-side bonding structure 938 and to a respective one of the die-side bonding structures (780, 880).

Each set of at least one semiconductor die (700, 800) may be attached to a respective redistribution structure 920 through a respective set of first solder material portions 940. Each of the at least one substrate trench within a unit area UA may be located outside an area including the at least one semiconductor die (700, 800) in the unit area UA in a plan view. The plan view is a view along a vertical direction, which is the direction that is perpendicular to the planar top surface of the redistribution structure layer.

Referring to FIG. 3C, a high bandwidth memory (HBM) die 810 is illustrated, which may be used as a memory die 800 within the exemplary structures of FIGS. 3A and 3B. The HBM die 810 may include a vertical stack of static random-access memory dies (811, 812, 813, 814, 815) that are interconnected to one another through microbumps 820 and are laterally surrounded by an epoxy molding material enclosure frame 816. The gaps between vertically neighboring pairs of the random-access memory dies (811, 812, 813, 814, 815) may be filled with a HBM underfill material portions 822 that laterally surrounds a respective set of microbumps 820. The HBM die 810 may comprise an array of memory-die metal bonding structures 880 configured to be bonded to a subset of an array of redistribution-side bonding structures 938 within a unit area UA. The HBM die 810 may be configured to provide a high bandwidth as defined under JEDEC standards, i.e., standards defined by The JEDEC Solid State Technology Association, but is not limited thereto.

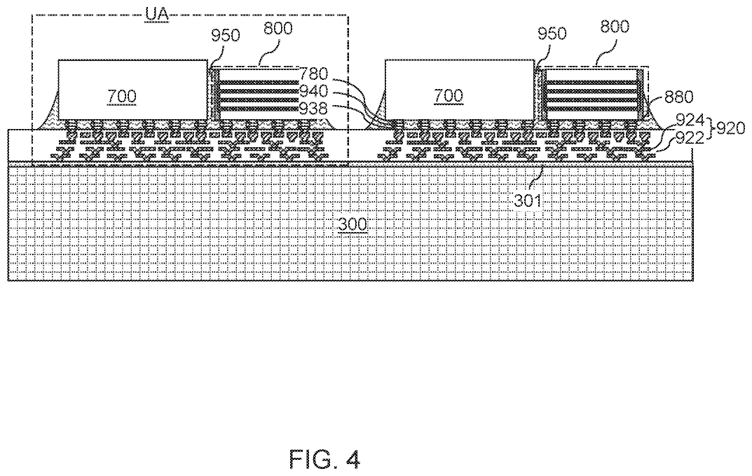

Referring to FIG. 4, a first underfill material may be applied into each gap between the redistribution structures 920 and sets of at least one semiconductor die (700, 800) that are bonded to the redistribution structures 920. The first underfill material may comprise any underfill material known in the art. A first underfill material portion 950 may be formed within each unit area UA between a redistribution structure 920 and an overlying set of at least one semiconductor die (700, 800). The first underfill material portions 950 may be formed by injecting the first underfill material around a respective array of first solder material portions 940 in a respective unit area UA. Any known underfill material application method may be used, which may be, for example, the capillary underfill method, the molded underfill method, or the printed underfill method.

Within each unit area UA, a first underfill material portion 950 may laterally surround, and contact, each of the first solder material portions 940 within the unit area UA. The first underfill material portion 950 may be formed around, and contact, the first solder material portions 940, the redistribution-side bonding structures 938, and the die-side bonding structures (780, 880) in the unit area UA.

Each redistribution structure 920 in a unit area UA comprises redistribution-side bonding structures 938. At least one semiconductor die (700, 800) comprising a respective set of die-side bonding structures (780, 880) is attached to the redistribution-side bonding structures 938 through a respective set of first solder material portions 940 within each unit area UA. Within each unit area UA, a first underfill material portion 950 laterally surrounds the redistribution-side bonding structures 938 and the die-side bonding structures (780, 880) of the at least one semiconductor die (700, 800).

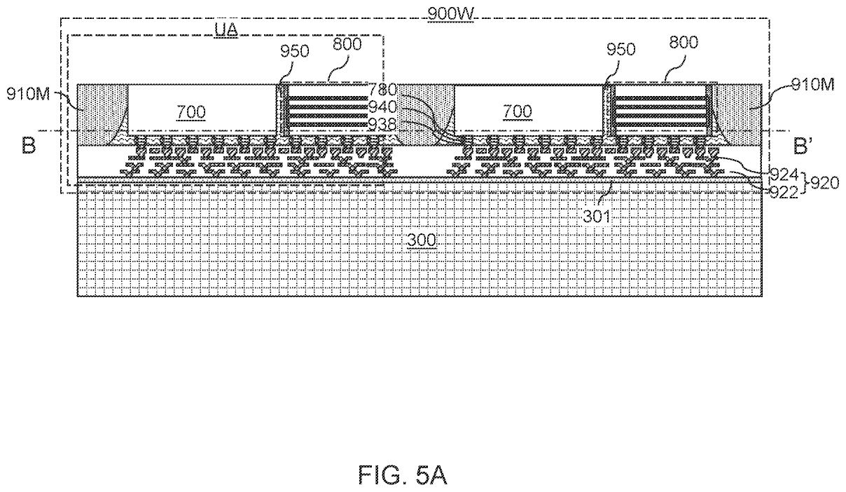

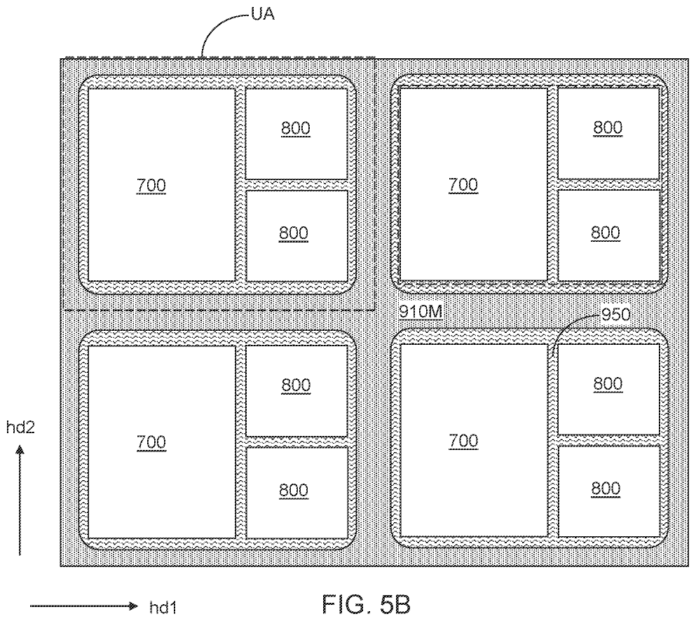

Referring to FIGS. 5A and 5B, an epoxy molding compound (EMC) may be applied to the gaps between contiguous assemblies of a respective set of semiconductor dies (700, 800) and a first underfill material portion 950.

The EMC may include an epoxy-containing compound that may be hardened (i.e., cured) to provide a dielectric material portion having sufficient stiffness and mechanical strength. The EMC may include epoxy resin, hardener, silica (as a filler material), and other additives. The EMC may be provided in a liquid form or in a solid form depending on the viscosity and flowability. Liquid EMC provides better handling, good flowability, less voids, better fill, and less flow marks. Solid EMC provides less cure shrinkage, better stand-off, and less die drift. A high filler content (such as 85% in weight) within an EMC may shorten the time in mold, lower the mold shrinkage, and reduce the mold warpage. Uniform filler size distribution in the EMC may reduce flow marks, and may enhance flowability. The curing temperature of the EMC may be lower than the release (debonding) temperature of the first adhesive layer 301 in embodiments in which the adhesive layer includes a thermally debonding material. For example, the curing temperature of the EMC may be in a range from 125° C. to 150° C.

The EMC may be cured at a curing temperature to form an EMC matrix 910M that laterally surrounds and embeds each assembly of a set of semiconductor dies (700, 800) and a first underfill material portion 950. The EMC matrix 910M includes a plurality of epoxy molding compound (EMC) die frames that may be laterally adjoined to one another. Each EMC die frame is a portion of the EMC matrix 910M that is located within a respective unit area UA. Thus, each EMC die frame laterally surrounds and embeds a respective a set of semiconductor dies (700, 800) and a respective first underfill material portion 950. Young's modulus of pure epoxy is about 3.35 GPa, and Young's modulus of the EMC may be higher than Young's modulus of pure epoxy by adding additives. Young's modulus of EMC may be greater than 3.5 GPa.

Portions of the EMC matrix 910M that overlies the horizontal plane including the top surfaces of the semiconductor dies (700, 800) may be removed by a planarization process. For example, the portions of the EMC matrix 910M that overlies the horizontal plane may be removed using a chemical mechanical planarization (CMP). The combination of the remaining portion of the EMC matrix 910M, the semiconductor dies (700, 800), the first underfill material portions 950, and the two-dimensional array of redistribution structures 920 comprises a reconstituted wafer 900W. Each portion of the EMC matrix 910M located within a unit area UA constitutes an EMC die frame. In some embodiments that the top surfaces (back surfaces) of the semiconductor dies 700 are higher than the top surfaces of the semiconductor dies 700 before this planarization process, both the semiconductor dies 700 and the EMC matrix 910M are polished until the semiconductor dies 800 are exposed.

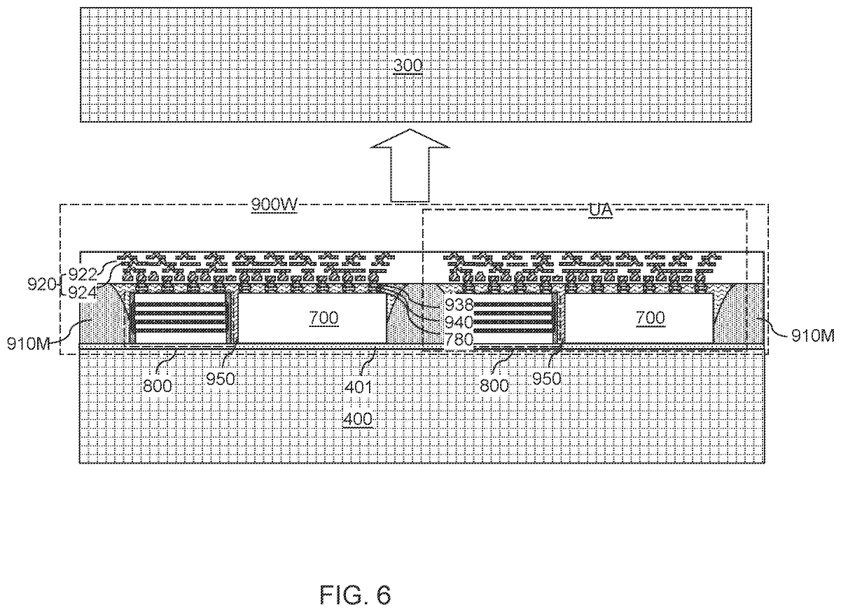

Referring to FIG. 6, a second adhesive layer 401 may be applied to the physically exposed planar surface of the reconstituted wafer 900W, i.e., the physically exposed surfaces of the EMC matrix 910M, the semiconductor dies (700, 800), and the first underfill material portions 950. In one embodiment, the second adhesive layer 401 may comprise a same material as, or may comprise a different material from, the material of the first adhesive layer 301. In embodiments in which the first adhesive layer 301 comprises a thermally decomposing adhesive material, the second adhesive layer 401 may comprise another thermally decomposing adhesive material that decomposes at a higher temperature, or may comprise a light-to-heat conversion material.

A second carrier substrate 400 may be attached to the second adhesive layer 401. The second carrier substrate 400 may be attached to the opposite side of the reconstituted wafer 900W relative to the first carrier substrate 300. Generally, the second carrier substrate 400 may comprise any material that may be used for the first carrier substrate 300. The thickness of the second carrier substrate 400 may be in a range from 500 microns to 2,000 microns, although lesser and greater thicknesses may also be used.

The first adhesive layer 301 may be decomposed by ultraviolet radiation or by a thermal anneal at a debonding temperature. In embodiments in which the first carrier substrate 300 includes an optically transparent material and the first adhesive layer 301 includes an LTHC layer, the first adhesive layer 301 may be decomposed by irradiating ultraviolet light through the transparent carrier substrate. The LTHC layer may be absorb the ultraviolet radiation and generate heat, which decomposes the material of the LTHC layer and cause the transparent first carrier substrate 300 to be detached from the reconstituted wafer 900W. In embodiments in which the first adhesive layer 301 includes a thermally decomposing adhesive material, a thermal anneal process at a debonding temperature may be performed to detach the first carrier substrate 300 from the reconstituted wafer 900W.

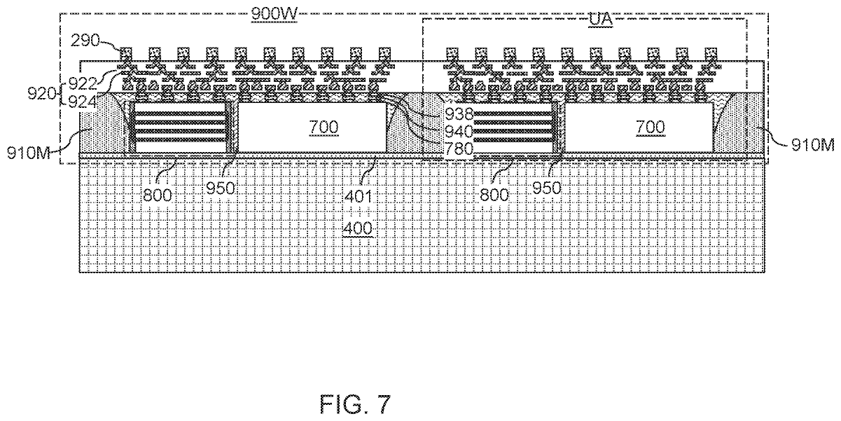

Referring to FIG. 7, fan-out bonding pads 928 and second solder material portions 290 may be formed by depositing and patterning a stack of at least one metallic material that may function as metallic bumps and a solder material layer. The metallic fill material for the fan-out bonding pads 928 may include copper. Other suitable materials are within the contemplated scope of disclosure. The thickness of the fan-out bonding pads 928 may be in a range from 5 microns to 100 microns, although lesser or greater thicknesses may also be used. The fan-out bonding pads 928 and the second solder material portions 290 may have horizontal cross-sectional shapes of rectangles, rounded rectangles, or circles. Other suitable shapes are within the contemplated scope of disclosure. In embodiments in which the fan-out bonding pads 928 are formed as C4 (controlled collapse chip connection) pads, the thickness of the fan-out bonding pads 928 may be in a range from 5 microns to 50 microns, although lesser or greater thicknesses may also be used. In some embodiments, the fan-out bonding pads 928 may be, or include, under bump metallurgy (UBM) structures. The configurations of the fan-out bonding pads 928 are not limited to be fan-out structures. Alternatively, the fan-out bonding pads 928 may be configured for microbump bonding (i.e., C2 bonding), and may have a thickness in a range from 30 microns to 100 microns, although lesser or greater thicknesses may also be used. In such an embodiment, the fan-out bonding pads 928 may be formed as an array of microbumps (such as copper pillars) having a lateral dimension in a range from 10 microns to 25 microns, and having a pitch in a range from 20 microns to 50 microns.

The fan-out bonding pads 928 and the second solder material portions 290 may be formed on the opposite side of the EMC matrix 910M and the two-dimensional array of sets of semiconductor dies (700, 800) relative to the redistribution structure layer. The redistribution structure layer includes a three-dimensional array of redistribution structures 920. Each redistribution structure 920 may be located within a respective unit area UA. Each redistribution structure 920 may include redistribution dielectric layers 922, redistribution wiring interconnects 924 embedded in the redistribution dielectric layers 922, and fan-out bonding pads 928. The fan-out bonding pads 928 may be located on an opposite side of the redistribution-side bonding structures 938 relative to the redistribution dielectric layers 922, and may be electrically connected to a respective one of the redistribution-side bonding structures 938.

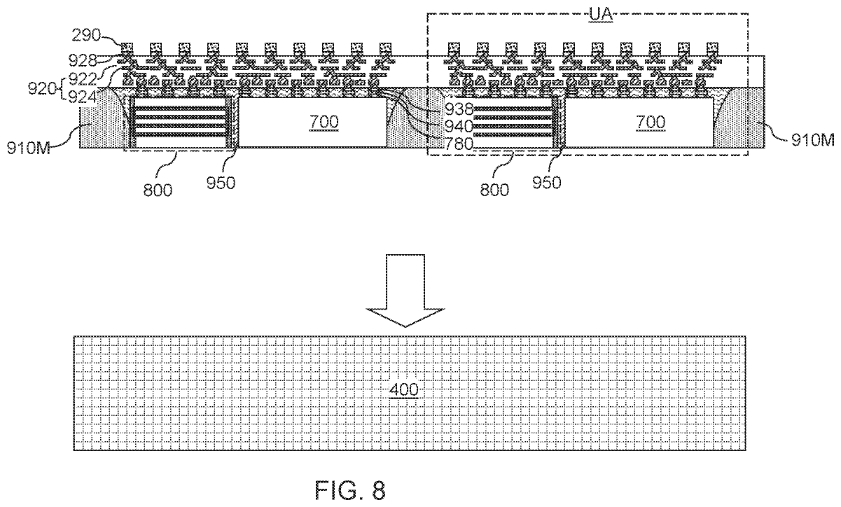

Referring to FIG. 8, the second adhesive layer 401 may be decomposed by ultraviolet radiation or by a thermal anneal at a debonding temperature. In embodiments in which the second carrier substrate 400 includes an optically transparent material and the second adhesive layer 401 includes an LTHC layer, the second adhesive layer 401 may be decomposed by irradiating ultraviolet light through the transparent carrier substrate. In embodiments in which the second adhesive layer 401 includes a thermally decomposing adhesive material, a thermal anneal process at a debonding temperature may be performed to detach the second carrier substrate 400 from the reconstituted wafer 900W.

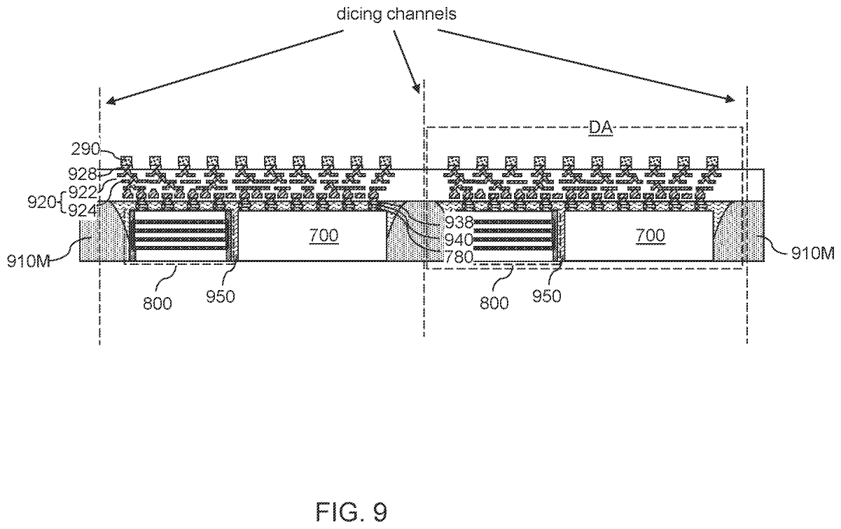

Referring to FIG. 9, the reconstituted wafer 900W including the fan-out bonding pads 928 may be subsequently diced along dicing channels by performing a dicing process. The dicing channels correspond to the boundaries between neighboring pairs of die areas DA. Each diced unit from the reconstituted wafer 900W may include a fan-out package 900. In other words, each diced portion of the assembly of the two-dimensional array of sets of semiconductor dies (700, 800), the two-dimensional array of first underfill material portions 950, the EMC matrix 910M, and the two-dimensional array of redistribution structures 920 constitutes a fan-out package 900. Each diced portion of the EMC matrix 910M constitutes a molding compound die frame 910. Each diced portion of the redistribution structure layer (which includes the two-dimensional array of redistribution structures 920) constitutes a redistribution structure 920.

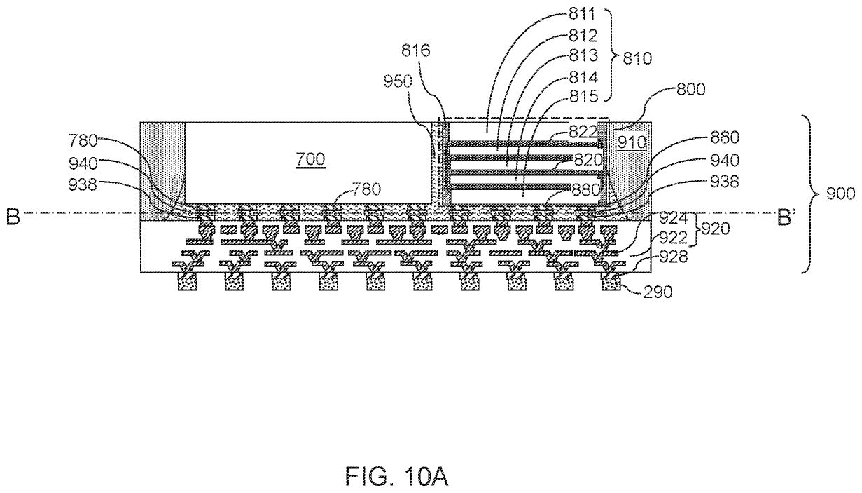

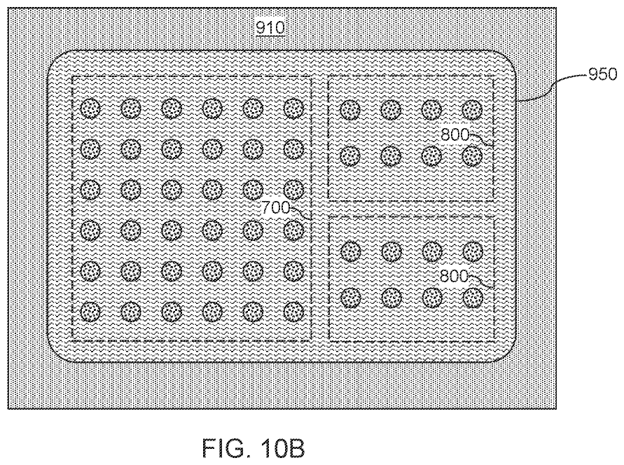

Referring to FIGS. 10A and 10B, a fan-out package 900 obtained by dicing the exemplary structure at the processing steps of FIG. 10 is illustrated. The fan-out package 900 comprises a redistribution structure 920 including redistribution-side bonding structures 938, at least one semiconductor die (700, 800) comprising a respective set of die-side bonding structures (780, 880) that is attached to the redistribution-side bonding structures 938 through a respective set of first solder material portions 940, a first underfill material portion 950 laterally surrounding the redistribution-side bonding structures 938 and the die-side bonding structures (780, 880) of the at least one semiconductor die (700, 800).

The fan-out package 900 may comprise a molding compound die frame 910 laterally surrounding the at least one semiconductor die (700, 800) and comprising a molding compound material. In one embodiment, the molding compound die frame 910 may include sidewalls that are vertically coincident with sidewalls of the redistribution structure 920, i.e., located within same vertical planes as the sidewalls of the redistribution structure 920. Generally, the molding compound die frame 910 may be formed around the at least one semiconductor die (700, 800) after formation of the first underfill material portion 950 within each fan-out package 900. The molding compound material contacts a peripheral portion of a planar surface of the redistribution structure 920.

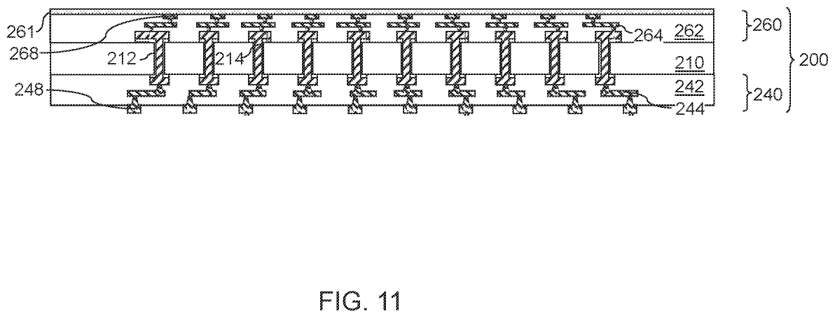

Referring to FIG. 11, a substrate package 200 is provided. The substrate package 200 may be a cored substrate package including a core substrate 210, or a coreless substrate package that does not include a package core. Alternatively, the substrate package 200 may include a system-on-integrated substrate package (SoIS) including redistribution layers and/or dielectric interlayers, at least one embedded interposer (such as a silicon interposer). Such a system-integrated substrate package may include layer-to-layer interconnections using solder material portions, microbumps, underfill material portions (such as molded underfill material portions), and/or an adhesion film. While the present disclosure is described using an exemplary substrate package, it is understood that the scope of the present disclosure is not limited by any particular type of substrate package and may include an SoIS. The core substrate 210 may include a glass epoxy plate including an array of through-plate holes. An array of through-core via structures 214 including a metallic material may be provided in the through-plate holes. Each through-core via structure 214 may, or may not, include a cylindrical hollow therein. Optionally, dielectric liners 212 may be used to electrically isolate the through-core via structures 214 from the core substrate 210.

The substrate package 200 may include board-side surface laminar circuit (SLC) 240 and a chip-side surface laminar circuit (SLC) 260. The board-side SLC may include board-side insulating layers 242 embedding board-side wiring interconnects 244. The chip-side SLC 260 may include chip-side insulating layers 262 embedding chip-side wiring interconnects 264. The board-side insulating layers 242 and the chip-side insulating layers 262 may include a photosensitive epoxy material that may be lithographically patterned and subsequently cured. The board-side insulating layers 242 and the chip-side insulating layers 262 may include dielectric materials, and may be referred to as board-side dielectric layers and chip-side dielectric layers. The board-side wiring interconnects 244 and the chip-side wiring interconnects 264 may include copper that may be deposited by electroplating within patterns in the board-side insulating layers 242 or the chip-side insulating layers 262. In some embodiments, the substrate package 200 may include a solder mask 261. The solder mask 261 may be deposited over the chip-side insulating layers 262 of the chip-side SLC 260 and top surfaces of the chip-side bonding pads 268.

In one embodiment, the substrate package 200 may include a chip-side surface laminar circuit 260 comprising chip-side wiring interconnects 264 connected to an array of chip-side bonding pads 268 that may be bonded to the array of second solder material portions 290, and a board-side surface laminar circuit 240 including board-side wiring interconnects 244 connected to an array of board-side bonding pads 248. The array of board-side bonding pads 248 is configured to allow bonding through solder balls. The array of chip-side bonding pads 268 may be configured to allow bonding through C4 solder balls. Generally, any type of substrate package 200 may be used. While the present disclosure is described using an embodiment in which the substrate package 200 includes a chip-side surface laminar circuit 260 and a board-side surface laminar circuit 240, embodiments are expressly contemplated herein in which one of the chip-side surface laminar circuit 260 and the board-side surface laminar circuit 240 is omitted, or is replaced with an array of bonding structures such as microbumps. In an illustrative example, the chip-side surface laminar circuit 260 may be replaced with an array of microbumps or any other array of bonding structures.

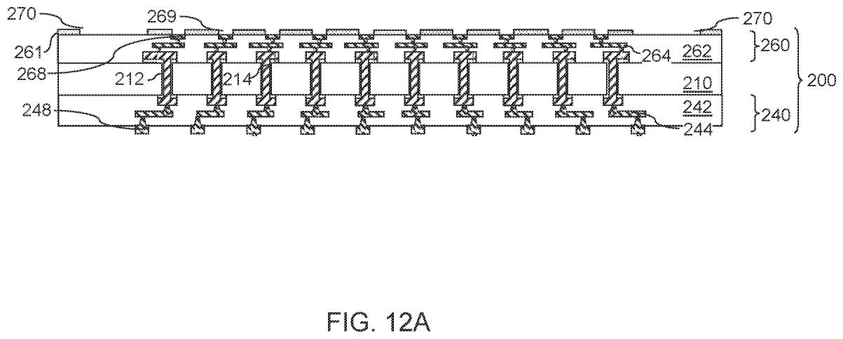

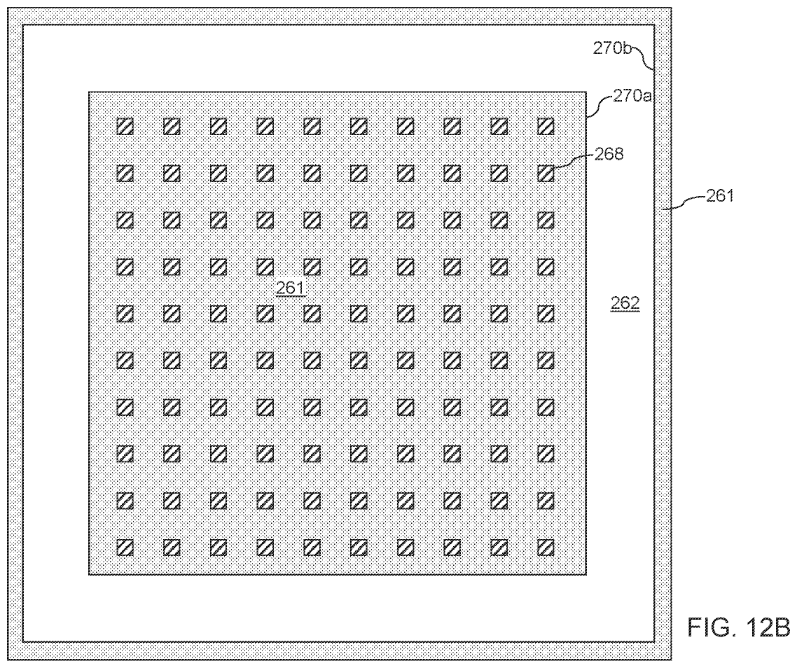

Referring to FIGS. 12A and 12B, the solder mask 261 may be lithographically patterned and etched to create openings 269 above the top surfaces of the chip-side bonding pads 268, such that the top surfaces of the chip-side bonding pads 268 may be exposed in preparation of forming a bonded connection with solder material in subsequent processes. In the same lithographic patterning process or in a different lithographic patterning process, the solder mask 261 may be lithographically patterned and etched to form at least one substrate trench 270 around the openings 269. In some embodiments, the depth of a substrate trench 270 formed through a lithographic patterning process may be in a range from 10 microns to 100 microns, such as 30 microns or any value that is not greater than the depth of the solder mask 261. In some embodiments, the depth of a substrate trench 270 may be 15 microns. In some embodiments, the solder mask 261 may be etched and the substrate trench 270 may be formed to expose a top surface of the chip-side insulating layers 262 as shown in FIGS. 12A and 12B. In some embodiments, the solder mask 261 may be etched and the substrate trench 270 may be formed such that a portion of the solder mask 261 remains at the bottom-most surface of the substrate trench 270 (i.e., a top surface of the chip-side insulating layers 262 is not exposed in the lithographic patterning process).

As illustrated in the top-down, or plan, view of FIG. 12B, the embodiment is shown to have a substrate trench 270 with sharp, squared, or perpendicular corners. However, other shapes and etching patterns of the substrate trench 270 may be contemplated in accordance with the scope of this disclosure. In some embodiments, the at least one substrate trench may include a frame-shaped inner sidewall 270a and a frame-shaped outer sidewall 270b that laterally surrounds the frame-shaped inner sidewall 270a, in which the frame-shaped inner sidewall 270a laterally surrounds the chip-side bonding pads 268 (i.e., to be ultimately connected to an array of solder material portions).

In some embodiments, the substrate trench 270 may be patterned and formed to have rounded corners, tapered corners, or be of nonuniform shapes. In some embodiments, the distance between an inner sidewall 270a of the substrate trench 270 and an outer sidewall 270b of the substrate trench 270 may be equidistant throughout the entire formation of the substrate trench 270. In some embodiments, the distances between the inner sidewall 270a and the outer sidewall 270b at the corner portions may be less than or greater than the distances between the inner sidewall 270a and the outer sidewall 270b along the vertical and horizontal linear portions of the substrate trench 270. In some embodiments, the distances between the inner sidewall 270a and the outer sidewall 270b along one or more of the vertical and horizontal linear portions of the substrate trench 270 may be less than or greater than the distances between the inner sidewall 270a and the outer sidewall 270b along other vertical and horizontal linear portions of the substrate trench 270.

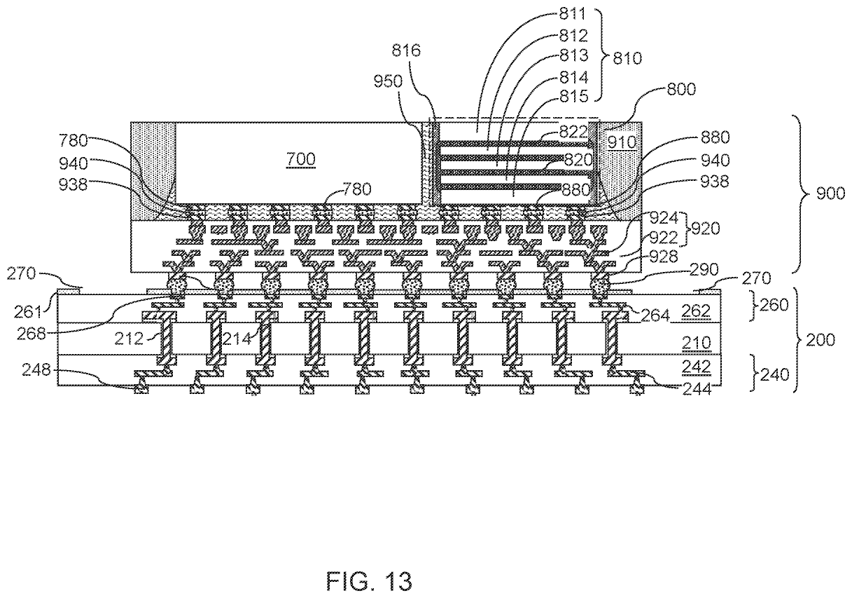

Referring to FIG. 13, the fan-out package 900 may be disposed over the substrate package 200 with an array of the second solder material portions 290 therebetween. In embodiments in which the second solder material portions 290 are formed on the fan-out bonding pads 928 of the fan-out package 900, the second solder material portions 290 may be disposed on the chip-side bonding pads 268 of the substrate package 200. A reflow process may be performed to reflow the second solder material portions 290, thereby inducing bonding between the fan-out package 900 and the substrate package 200. Each second solder material portion 290 may be bonded to a respective one of the fan-out bonding pads 928 and to a respective one of the chip-side bonding pads 268. In one embodiment, the second solder material portions 290 may include C4 solder balls, and the fan-out package 900 may be attached to the substrate package 200 through an array of C4 solder balls. Generally, the fan-out package 900 may be bonded to the substrate package 200 such that the redistribution structure 920 is bonded to the substrate package 200 by an array of solder material portions (such as the second solder material portions 290).

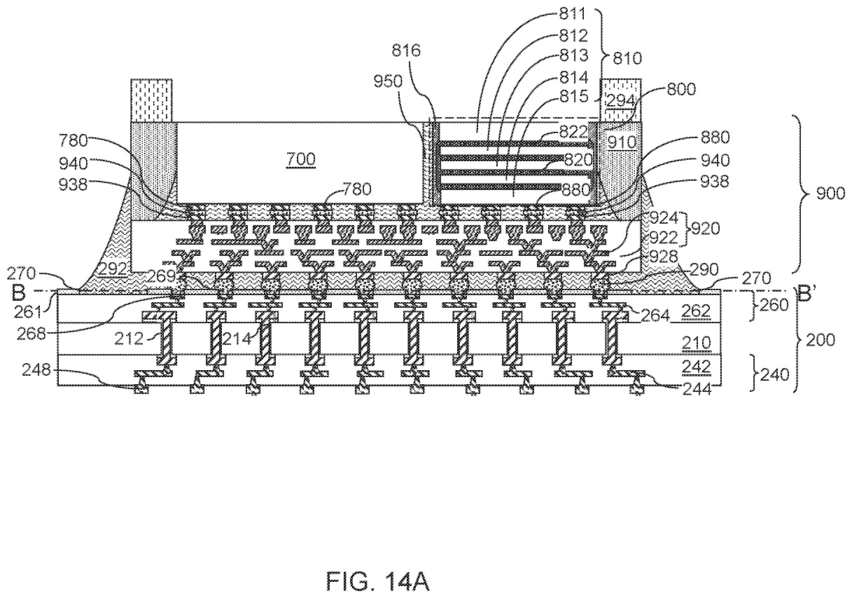

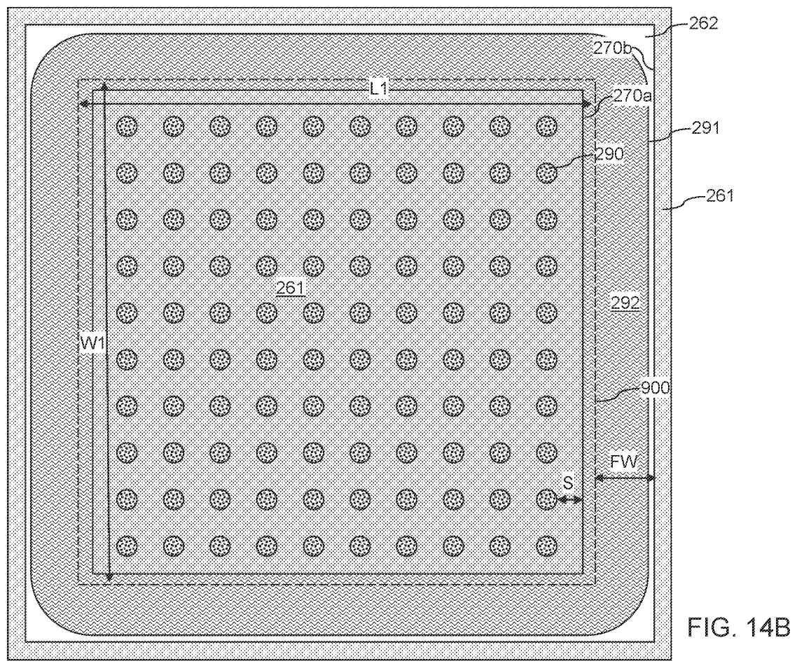

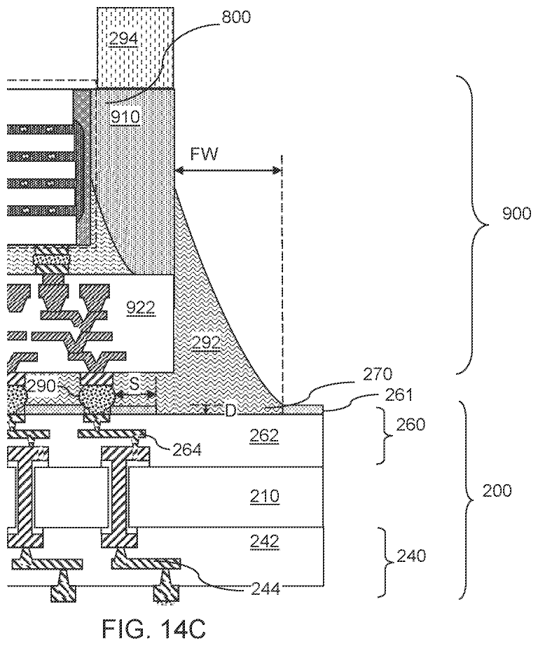

Referring to FIGS. 14A and 14B, a second underfill material portion 292 may be dispensed or otherwise formed around the second solder material portions 290 by applying and shaping a second underfill material. The second underfill material portion 292 may be formed by injecting the second underfill material around the array of second solder material portions 290 after the second solder material portions 290 are reflowed. Any known underfill material application method may be used, which may be, for example, the capillary underfill method, the molded underfill method, or the printed underfill method. For ease of illustration, an outer edge, or exposed surface, of the second underfill material portion 292 is shown as a straight line. However, it is to be noted that in actual applications, there may be a slight curvature to the exposed outer surface of the second underfill material portion 292.

The second underfill material portion 292 may be formed between the redistribution structure 920 and the substrate package 200. According to an aspect of the present disclosure, the second underfill material portion 292 may be formed directly on each sidewall of the molding compound die frame 910 and directly on segments of a top surface and at least one sidewall of one, and/or each, of the at least one substrate trench 270. The second underfill material portion 292 may contact each of the second solder material portions 290 (which may be C4 solder balls or C2 solder caps), and may contact vertical sidewalls of the fan-out package 900. The second underfill material portion laterally surrounds, and contacts, the array of second solder material portions 290 and the fan-out package 900.

In some embodiments, the manufacturing processes described with reference to FIGS. 13 and 14A-14B may be reversed. For example, prior to connecting the fan-out package 900 to the substrate package 900 via the second solder material portions 290, the second underfill material portion 292 may be dispensed or otherwise formed onto the surface of the substrate package 200. The second solder material portions 290 may separately be attached to the fan-out package 900. The fan-out package 900 with second solder material portions 290 may then be pressed to the substrate package 200 having the second underfill material portion 292, such that the second underfill material portion 292 disperses between the second solder material portions 290 beneath the fan-out package 900 and disperses outward from the periphery of the fan-out package 900. Flux, solder reflow, and underfill cure processes may then be implemented to affix the substrate package 200 to the fan-out package 900 via the second solder material portions 290 and the second underfill material portion 292.

Referring back to FIGS. 14A and 14B, in one embodiment, the fan-out package 900 comprises a molding compound die frame 910 that laterally surrounds the at least one semiconductor die (700, 800) and contacting a peripheral portion of a top surface of the redistribution structure 920. The second underfill material portion 292 may be formed directly on sidewalls of the molding compound die frame 910. In one embodiment, the second underfill material portion 292 may cover a first portion of each of the at least one substrate trench 270, and may not cover a second portion of each of the at least one substrate trench 270 that is located outside the first portion of each of the at least one substrate trench 270. For example, the second underfill material portion 292 may only fill a portion of the substrate trench 270 that is nearest to the fan-out package 900 and a portion of the substrate trench 270 that is furthest from the fan-out package 900 remains unfilled by the second underfill material portion (i.e., portions of the top surfaces of the chip-side insulating layers 262 within the substrate trench 270 remain exposed and not covered by the second underfill material portion 292).

Optionally, a stabilization structure 294, such as a cap structure or a ring structure, may be attached to the assembly of the fan-out package 900 and the substrate package 200 to reduce deformation of the assembly during subsequent processing steps and/or during usage of the assembly.

In one embodiment, the fan-out package 900 may have a rectangular horizontal cross-sectional shape having a first length L1 along a first horizontal direction and having a first width W1 along a second horizontal direction that is perpendicular to the first horizontal direction. In one embodiment, an outer periphery 291 of the second underfill material portion 292 that defines the outermost extent of the second underfill material portion 292 after being dispensed may be equidistant, or may be substantially equidistant, from the sidewalls of the fan-out package 900. The lateral distance (i.e., the horizontal distance) between the outer periphery 291 of the second underfill material portion 292 and the most proximal one of the sidewalls of the fan-out package 900 is herein referred to as a filet width FW, which may be in a range from 500 microns to 1100 microns, although lesser and greater lateral dimensions may also be used.

In one embodiment, an inner periphery, or inner sidewall 270a, of the substrate trench 270 that defines the innermost extent of the substrate trench 270 with respect to the fan-out package 900 may be equidistant, or may be substantially equidistant, from the sidewalls of the fan-out package 900. In one embodiment, an inner periphery, or inner sidewall 270a, of the substrate trench 270 that defines the innermost extent of the substrate trench 270 with respect to the fan-out package 900 may be equidistant, or may be substantially equidistant, from the nearest portions of the second solder material portions 290. The lateral distance (i.e., the horizontal distance) between the inner sidewall 270a and the most proximal one of the sidewalls of the second solder material portions 290 is herein referred to as a distance S, which may be in a range from 100 microns to 300 microns, although lesser and greater lateral dimensions may also be used.

In some embodiments, the inner sidewall 270a of the substrate trench 270 may be vertically beneath the fan-out package 900, such that the inner sidewall 270a is laterally or horizontally between a proximal second solder material portion 290 and a proximal sidewall of the fan-out package 900. For example, a portion of the fan-out package 900 may be vertically above, or may overlap, the substrate trench 270. In some embodiments, the inner sidewall 270a of the substrate trench 270 may be vertically outside a periphery of the sidewalls of the fan-out package 900, such that a portion of the fan-out package 900 may not be vertically above, or may not overlap, the substrate trench 270. In some embodiments, the inner sidewall 270a and outer sidewall 270b of the substrate trench 270 may be vertically beneath the fan-out package 900, such that the inner sidewall 270a and outer sidewall 270b are laterally or horizontally between a proximal second solder material portion 290 and a proximal sidewall of the fan-out package 900.

FIG. 14C illustrates a magnified view of a region of the exemplary structure as shown in FIG. 14A. Referring to FIG. 14C, various dimensions with respect to the substrate trench 270, the second underfill material portion 292, and a sidewall of the fan-out package 900 are shown. A vertical distance between a bottommost surface of the substrate trench 270 and a topmost surface of the substrate package (e.g., topmost surface of the solder mask 261) is herein referred to as a substrate trench depth D, which may be in a range from 10 microns to 100 microns, although lesser and greater vertical dimensions may also be used.

The substrate trench 270 may function as a repository for the second underfill material portion 292 to reduce the filet width FW. Reducing the filet width FW may reduce the total top surface area of the substrate package 200 covered by the second underfill material portion 292, therefore freeing up more surface area for other components, such as surface-mount devices (SMDs) and board stiffeners (not shown). Fillet width FW may be reduced by decreasing the distance S and increasing both the width of the substrate trench 270 (i.e., width between the inner sidewall 270a and outer sidewall 270b) and the depth D. Adjusting the dimensions of the substrate trench accordingly to maximize volume of the substrate trench may allow more of the second underfill material portion 292 to be dispensed into the substrate trench 270 and therefore less of the second underfill material portion 292 may be dispensed outward across the top surface of the substrate package 200 (i.e., fillet width FW is reduced). Reducing the fillet width FW also benefits the overall structure of the semiconductor package by reducing the total mechanical stress on the second underfill material portion 292, and in turn, the fan-out package 900 and corresponding interconnectors contacting the second underfill material portion 292, exerted onto the second underfill material portion 292 during deformation or bending of the substrate package 900. In other words, reducing the total surface area of the substrate package 200 that the second underfill material portion 292 covers may reduce the overall mechanical stress exerted onto the second underfill material portion 292.

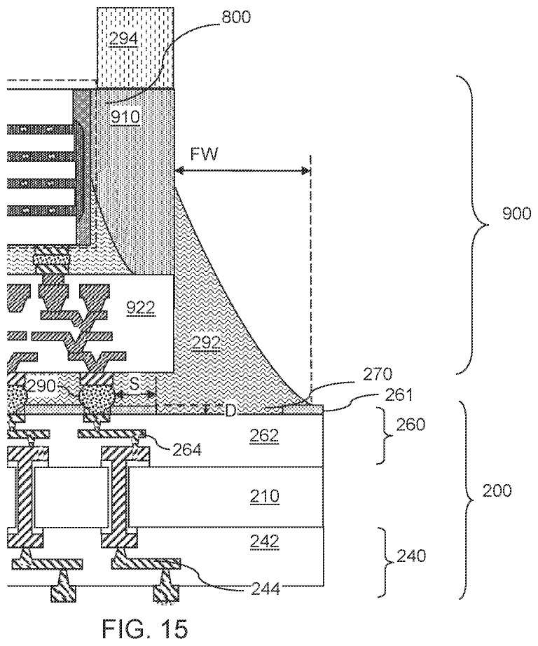

FIG. 15 illustrates a first alternative embodiment of the exemplary structure. In some embodiments, when dispensing the second underfill material portion 292 as described with reference to FIGS. 14A and 14B, some amount of the second underfill material portion 292 may continue to flow over the outer sidewall 270b of the substrate trench 270 and onto a top surface of the substrate package 200 (e.g., top surface of the solder mask 261). In such an embodiment, the substrate trench 270 still functions as a repository for the second underfill material portion 292, therefore reducing the spread of the second underfill material portion 292 outwards from proximate sidewalls of the fan-out package 900 (i.e., reducing fillet width FW) and freeing up board space.

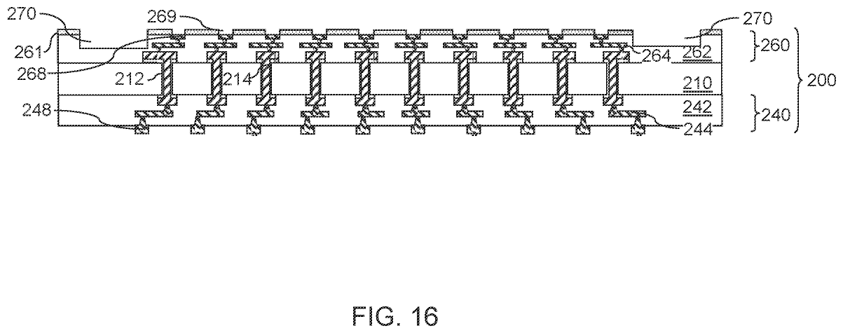

Referring to FIG. 16, a second alternative embodiment of the exemplary structure is illustrated. Continuing from the embodiment and manufacturing process after disposing the solder mask 261 as described in reference to FIG. 11, a substrate trench 270 may be formed through computer numerical control (CNC) machining, or other known drilling, milling or physical etching techniques. The substrate trench 270 may be drilled or otherwise formed to extend beyond the depth of the solder mask 261 and into the chip-side insulating layers 262. The substrate trench 270 may be formed to have a depth in the range of 10 microns to 100 microns, such as 70 microns or any value that is not greater than the depth of the substrate package 200. In some embodiments, the substrate trench 270 may extend into multiple layers through the substrate trench, such as through one or more of the chip-side insulating layers 262, the core substrate 210, and the board-side insulating layers 242. Before or after forming the substrate trench 270, the solder mask 261 may be lithographically patterned to create openings 269 above the top surfaces of the chip-side bonding pads 268, such that the top surfaces of the chip-side bonding pads 268 may be exposed in preparation of forming a bonded connection with solder material in subsequent processes.

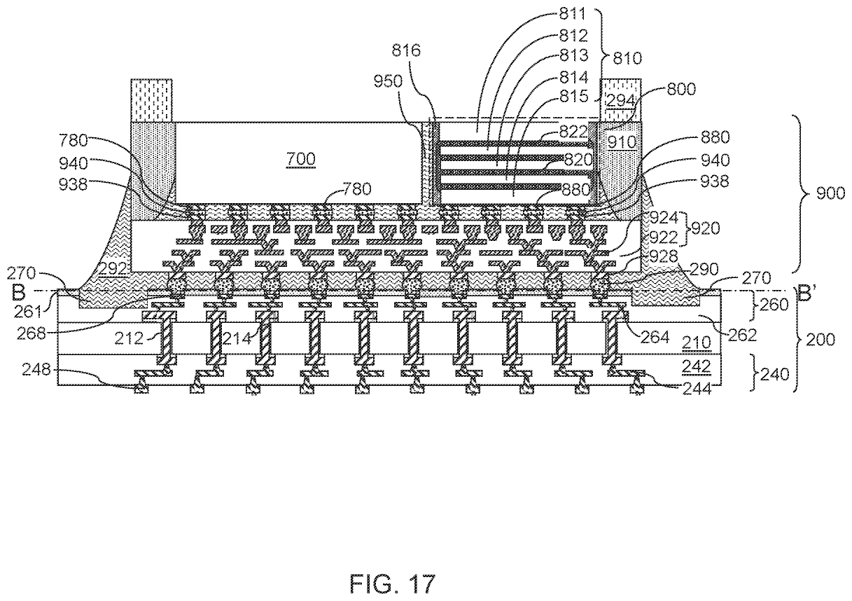

After forming the substrate trench 270, the manufacturing processes as described with reference to FIGS. 13-14B may be performed in a similar manner resulting in the alternate embodiment as illustrated in FIG. 17. Referring to FIG. 17, the second underfill material portion 292 may be dispensed, and the volume of the substrate trench 270 may be filled with the second underfill material portion 292. Thus, more of the second underfill material portion 292 may be dispensed within the substrate trench 270 and less of the second underfill material portion 292 may extend outward from the fan-out package 900 over surface of substrate package 200. A deeper and wider substrate trench 270 may allow reduction of the fillet FW, which opens up more room for other components including SMDs and board stiffeners (not shown). At least one substrate trench 270 may be formed in the solder mask 261. Each of the at least one substrate trench 270 may have an inner sidewall located between an outer sidewall of the at least one substrate trench 270 and proximal edges of the chip-side bonding pads 268.

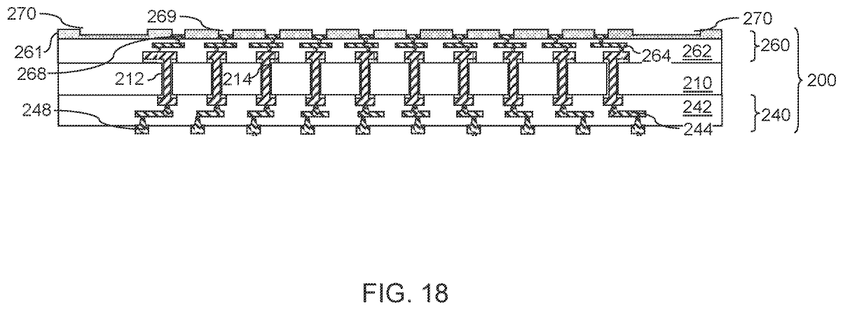

Referring to FIG. 18, a third alternative embodiment of the exemplary structure is illustrated. Continuing from the embodiment and manufacturing process after disposing the solder mask 261 as described in reference to FIG. 11, a substrate trench 270 may be formed through lithography. The solder mask 261 may be lithographically patterned and etched to create openings 269 above the top surfaces of the chip-side bonding pads 268, such that the top surfaces of the chip-side bonding pads 268 may be exposed in preparation of forming a bonded connection with solder material in subsequent processes. In the same lithographic patterning process or in a different lithographic patterning process, the solder mask 261 may be lithographically patterned and etched to form at least one substrate trench 270 around the openings 269. In some embodiments, the depth of a substrate trench 270 formed through a lithographic patterning process may be in a range from 10 microns to 100 microns, such as 30 microns or any value that is not greater than the depth of the solder mask 261. In some embodiments, the depth of a substrate trench 270 may be 15 microns. In some embodiments, the solder mask 261 may be etched and the substrate trench 270 may be formed to expose a top surface of the chip-side insulating layers 262. In some embodiments, the solder mask 261 may be etched and the substrate trench 270 may be formed such that a portion of the solder mask 261 remains at the bottom-most surface of the substrate trench 270 as illustrated in FIG. 18 (i.e., a top surface of the chip-side insulating layers 262 is not exposed in the lithographic patterning process).

In some embodiments, top surfaces of the chip-side bonding pads 268 may be in a same horizontal plane as a top surface of the chip-side insulating layers 262 in a cross-sectional view. In some embodiments, sidewalls and top surfaces of the chip-side bonding pads 268 may extend vertically above a top surface of the chip-side insulating layers 262 in a cross-sectional view as illustrated in FIG. 18. In such embodiments, exposed top surfaces of the chip-side bonding pads 268 may be at a lower, same, or higher horizontal plane as the bottommost surface of the substrate trench 270 in a cross-sectional view.

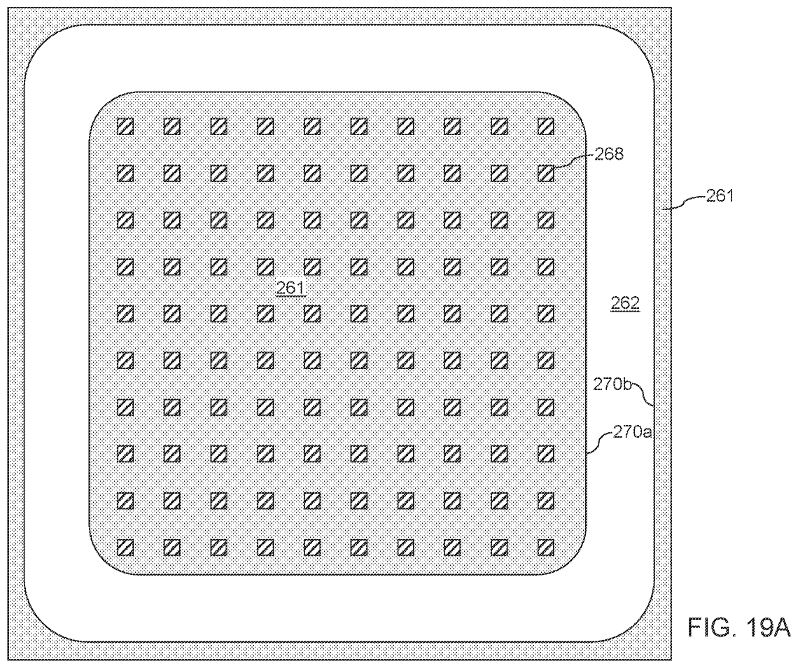

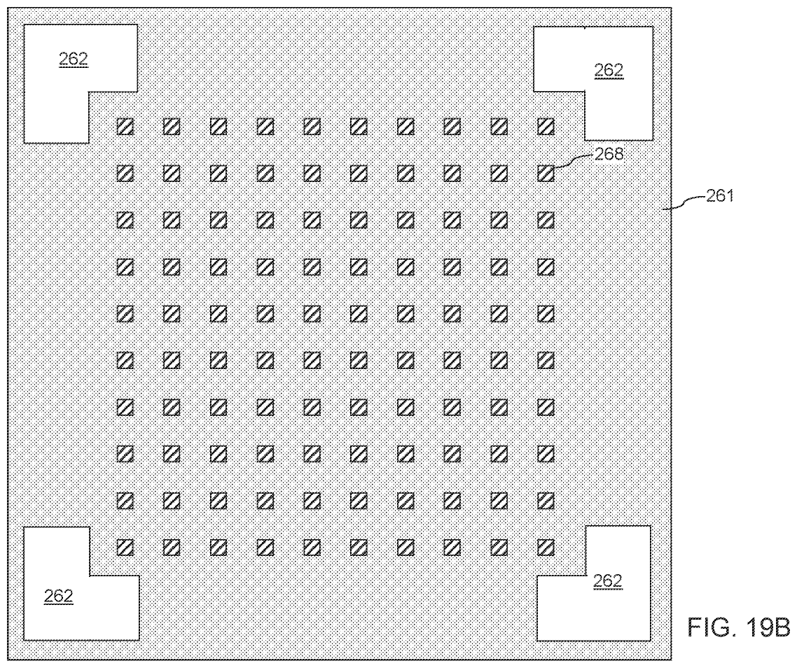

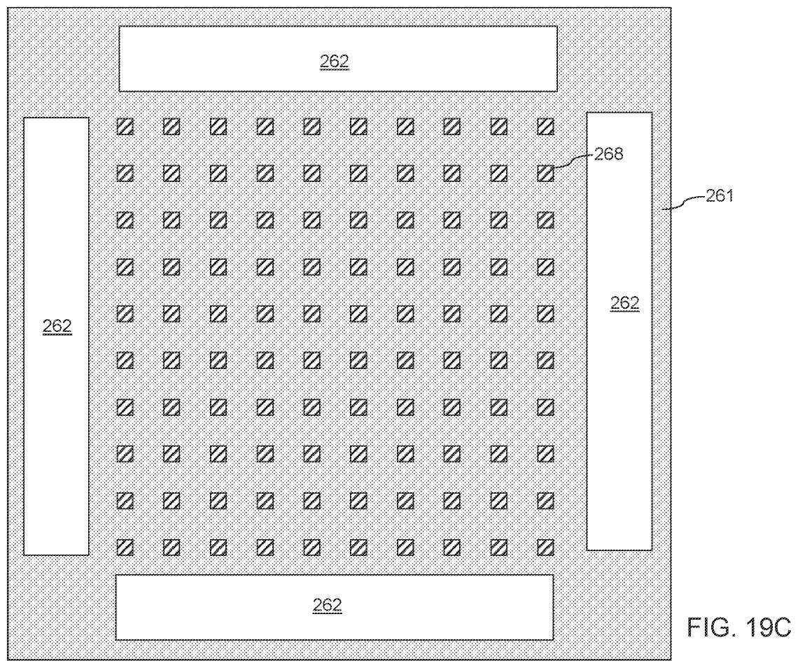

Referring to FIG. 19A, a third alternative embodiment of the exemplary structure is illustrated. As compared to the top-down view of the exemplary structure as illustrated in FIG. 12 which shows a substrate trench 270 having squared, or perpendicular corners, the substrate trench 270 of FIG. 19A may have curved, rounded, or tapered corners. An inner sidewall 270a of the substrate trench 270 may have rounded corners and an outer sidewall 270b of the substrate trench may have rounded corners. The inner sidewall 270a and the outer sidewall 270b may laterally surround the chip-side bonding pads 268. In some embodiments, the distance between the inner sidewall 270a and the outer sidewall 270b may be equidistant throughout the entire formation of the substrate structure 270. In some embodiments, the distances between the inner sidewall 270a and the outer sidewall 270b at the corner portions may be less than or greater than the distances between the inner sidewall 270a and the outer sidewall 270b along the vertical and horizontal linear portions of the substrate trench 270. In some embodiments, the distances between the inner sidewall 270a and the outer sidewall 270b along one or more of the vertical and horizontal linear portions of the substrate trench 270 may be less than or greater than the distances between the inner sidewall 270a and the outer sidewall 270b along other vertical and horizontal linear portions of the substrate trench 270.

Referring to FIG. 19B, a fourth alternative embodiment of the exemplary structure is illustrated. As compared to the top-down view of the exemplary structure as illustrated in FIG. 12 which shows a single substrate trench 270 having squared, or perpendicular corners, the substrate package 200 of FIG. 19B may have a plurality of L-shaped substrate trenches 270 located outside corner regions of the chip-side bonding pads 268. Each L-shaped substrate trench 270 may have a maximum length along a lengthwise direction and a maximum width along a widthwise direction, such that the maximum width length and maximum length of each L-shaped substrate trench 270 do not encroach a proximal sidewall of another L-shaped substrate trench 270. For example, a first L-shaped substrate trench 270 and a second L-shaped substrate trench 270 may have portions that come close to each other, but may not converge to create a single substrate trench. In some embodiments, each L-shaped substrate trench 270 may have curved corners in a plan view, as opposed to the perpendicular, squared corners as illustrated in FIG. 19B.

Referring to FIG. 19C, a fifth alternative embodiment of the exemplary structure is illustrated. As compared to the top-down view of the exemplary structure as illustrated in FIG. 12 which shows a single substrate trench 270 having squared, or perpendicular corners, the substrate package 200 of FIG. 19C may have a plurality of rectangular substrate trenches 270 located about side regions of the chip-side bonding pads 268. Each rectangular-shaped substrate trench 270 may have a maximum length along a lengthwise direction and a maximum width along a widthwise direction, such that the maximum width length and maximum length of each rectangular-shaped substrate trench 270 do not encroach a proximal sidewall of another rectangular-shaped substrate trench 270. For example, a first rectangular-shaped substrate trench 270 and a second rectangular-shaped substrate trench 270 may have portions that come close to each other at a corner with respect to the chip-side bonding pads 268, but may not converge to create a single substrate trench. In some embodiments, the at least one substrate trench 270 may include a plurality of rectangular substrate trenches 270 located about corner regions of the fan-out package 900 in a plan view, wherein the plurality of rectangular substrate trenches 270 have inner sidewalls that are parallel to proximal sidewalls of the fan-out package 900 in a plan view.

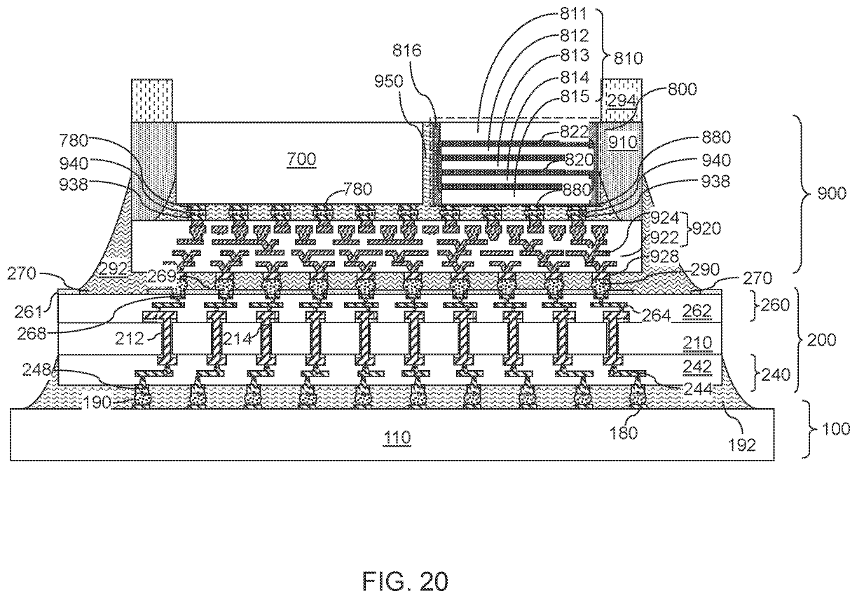

Referring to FIG. 20, a printed circuit board (PCB) 100 including a PCB substrate 110 and PCB bonding pads 180 may be provided. The PCB 100 includes a printed circuitry (not shown) at least on one side of the PCB substrate 110. An array of solder joints 190 may be formed to bond the array of board-side bonding pads 248 to the array of PCB bonding pads 180. The solder joints 190 may be formed by disposing an array of solder balls between the array of board-side bonding pads 248 and the array of PCB bonding pads 180, and by reflowing the array of solder balls. An underfill material portion 192 may be formed around the solder joints 190 by applying and shaping an underfill material. The substrate package 200 is attached to the PCB 100 through the array of solder joints 190. It is to be noted that the embodiment shown in FIG. 20 implements the embodiment including substrate trench 270 as illustrated in FIGS. 14A-14C. However, any and all embodiments, including embodiments illustrated in FIGS. 15-18C, may be implemented in a similar fashion as described with references to FIG. 20.

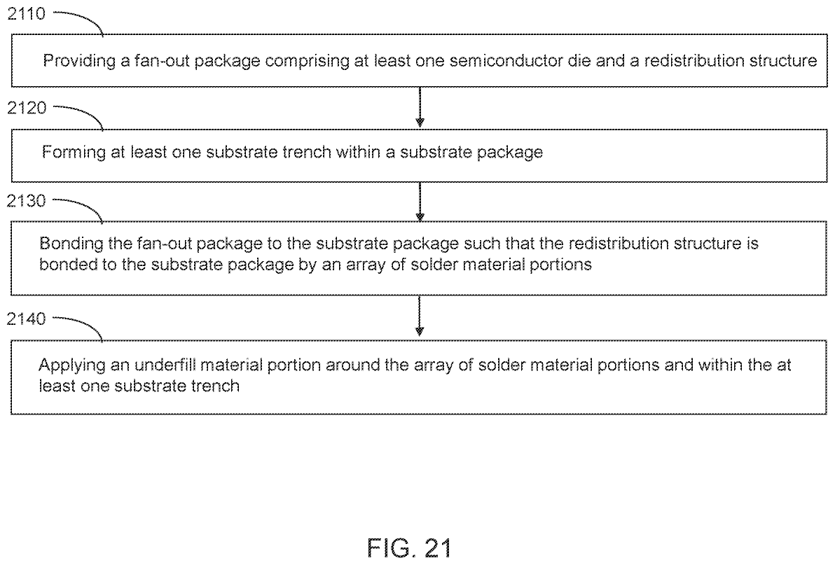

Referring to FIG. 21, a flowchart illustrates steps for forming an exemplary structure according to an embodiment of the present disclosure.

Referring to step 2110 and FIGS. 1A-10B, a package 900 (e.g., fan-out package 900) comprising at least one semiconductor die (700, 800) and a redistribution structure 920 may be provided.

Referring to step 2120 and FIGS. 11-12B and 16-18C, at least one substrate trench 270 may be formed within a substrate package 200. In some embodiments, forming the at least one substrate trench 270 within the substrate package 200 may further include forming the at least one substrate trench 270 within the substrate package 200 by lithographically patterning a solder mask 261 of the substrate package 200. In some embodiments, forming the at least one substrate trench 270 within the substrate package 200 may further include forming the at least one substrate trench 270 within the substrate package 200 by computer numerical control (CNC) machining chip-side insulating layers 262 of the substrate package 200. In some embodiments, forming the at least one substrate trench 270 within the substrate package 200 may further include forming an inner wall (e.g., 270a) and an outer wall (e.g., 270b) of the at least one substrate trench 270, wherein a periphery of an area of the package 900 is located between the inner wall (e.g., 270a) and the outer wall (e.g., 270b) of the at least one substrate trench 270 in a plan view.

Referring to step 2130 and FIG. 13, the package 900 may be bonded to the substrate package 200 such that the redistribution structure 920 is bonded to the substrate package 200 by solder material portions (e.g., second solder material portions 290).

Referring to step 2140 and FIGS. 14A-15 and 17, an underfill material portion (e.g., second underfill material portion 292) may be applied or otherwise dispensed around the solder material portions (e.g., second solder material portions 290) and within the at least one substrate trench 270.

Referring to all drawings and according to various embodiments of the present disclosure, a semiconductor structure is provided, which may include: a package 900 comprising bonding pads (e.g., fan-out bonding pads 928); a substrate package 200 that may include chip-side bonding pads 268 and at least one substrate trench 270, in which the at least one substrate trench 270 extends vertically below a top surface of the substrate package 200; solder material portions (e.g., second solder material portions 290) bonded to the chip-side bonding pads 268 and the fan-out bonding pads 928; and a second underfill material portion 292 laterally surrounding the solder material portions (e.g., second solder material portions 290) and dispensed within the at least one substrate trench 270.

In some embodiments, the package may be a fan-out package 900 that may include at least one semiconductor die (700, 800), a redistribution structure 920 that may include fan-out bonding pads 928 and a first underfill material portion 950 located between the at least one semiconductor die (700, 800) and the redistribution structure 920.

In some embodiments, the at least one substrate trench 270 may include an inner sidewall (e.g., 270a) and an outer sidewall (e.g., 270b) that are equidistant to each other throughout the at least one substrate trench 270. In one embodiment, a lateral distance between an outer periphery of the second underfill material portion 292 and a proximal sidewall of the package 900 may be within a range of 500 microns to 1100 microns. In one embodiment, a lateral distance between an inner sidewall (e.g., 270a) of the at least one substrate trench 270 and a proximal edge of a solder material portion of the solder material portions (e.g., second solder material portions 290) may be within a range of 100 microns to 300 microns. In some embodiments, the at least one substrate trench 270 may have a depth that is within a range of 10 microns to 100 microns.

In some embodiments, a bottom surface of the at least one substrate trench 270 may be vertically below a bottom surface of a solder mask 261 of the substrate package 200 in a cross-section view. In some embodiments, an inner sidewall (e.g., 270a) of the at least one substrate trench 270 may be located inside a periphery of an area of the package 900 in a plan view. In some embodiments, an outer sidewall (e.g., 270b) of the at least one substrate trench 270 may be located inside the periphery of the area of the package 900 in a plan view. In some embodiments, an outer periphery of the second underfill material portion 292 may be located between an inner sidewall (e.g., 270a) of the at least one substrate trench 270 and an outer sidewall (e.g., 270b) of the at least one substrate trench 270.

In some embodiments, the at least one substrate trench 270 may include a frame-shaped inner sidewall (e.g., 270a) and a frame-shaped outer sidewall (e.g., 270b) that laterally surrounds the frame-shaped inner sidewall (e.g., 270a), in which the frame-shaped inner sidewall (e.g., 270a) laterally surrounds the solder material portions (e.g., second solder material portions 290). In some embodiments, the frame-shaped inner sidewall (e.g., 270a) and the frame-shaped outer sidewall (e.g., 270b) may have rounded corners in a plan view proximate to corner regions of the package 900. In some embodiments, the at least one substrate trench 270 may include a plurality of L-shaped substrate trenches in a plan view proximate to corner regions of the package 900. In some embodiments, the at least one substrate trench 270 may include a plurality of rectangular substrate trenches in a plan view located adjacent to corner regions of the package 900, in which the plurality of rectangular substrate trenches have inner sidewalls that are parallel to proximal sidewalls of the package 900 in a plan view.

Referring to all drawings and according to various embodiments of the present disclosure, a substrate package 200 is provided, which may include: a chip-side surface laminar circuit (SLC) 260 that may include chip-side insulating layers 262, chip-side wiring interconnects 264 embedded within the chip-side insulating layers 262, and chip-side bonding pads 268 embedded within the chip-side insulating layers 262 and electrically connected to the chip-side wiring interconnects 264; a solder mask 261 deposited over the chip-side insulating layers 262 and top surfaces of the chip-side bonding pads 268; and at least one substrate trench 270 formed in the solder mask 261, in which the at least one substrate trench 270 has an inner sidewall (e.g., 270a) located between an outer sidewall (e.g., 270b) of the at least one substrate trench 270 and proximal edges of the chip-side bonding pads 268.

In some embodiments, the at least one substrate trench 270 may extend vertically through the solder mask 261 and into the chip-side insulating layers 262, in which the inner sidewall (e.g., 270a) and the outer sidewall (e.g., 270b) are in contact with sidewalls of the chip-side insulating layers 262 and sidewalls of the solder mask 261. In some embodiments, the at least one substrate trench 270 may have a depth that is within a range of 10 microns to 100 microns.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure comprising:
a package comprising bonding pads;
a substrate package comprising:
chip-side bonding pads; and
at least one substrate trench, wherein the at least one substrate trench extends vertically below a top surface of the substrate package;
solder material portions bonded to the chip-side bonding pads and the bonding pads; and
a second underfill material portion laterally surrounding the solder material portions and dispensed within the at least one substrate trench.

2. The semiconductor structure of claim 1, wherein the at least one substrate trench comprises an inner sidewall and an outer sidewall that are equidistant to each other throughout the at least one substrate trench.

3. The semiconductor structure of claim 1, wherein a lateral distance between an outer periphery of the second underfill material portion and a proximal sidewall of the package is within a range of 500 microns to 1100 microns.

4. The semiconductor structure of claim 1, wherein a lateral distance between an inner sidewall of the at least one substrate trench and a proximal edge of a solder material portion of the solder material portions is within a range of 100 microns to 300 microns.

5. The semiconductor structure of claim 1, wherein the at least one substrate trench has a depth that is within a range of 10 microns to 100 microns.

6. The semiconductor structure of claim 5, wherein a bottom surface of the at least one substrate trench is vertically below a bottom surface of a solder mask of the substrate package in a cross-section view.

7. The semiconductor structure of claim 1, wherein an inner sidewall of the at least one substrate trench is located inside a periphery of an area of the package in a plan view.

8. The semiconductor structure of claim 7, wherein an outer sidewall of the at least one substrate trench is located inside the periphery of the area of the package in a plan view.

9. The semiconductor structure of claim 1, wherein an outer periphery of the second underfill material portion is located between an inner sidewall of the at least one substrate trench and an outer sidewall of the at least one substrate trench.

10. The semiconductor structure of claim 1, wherein:
the at least one substrate trench comprises a frame-shaped inner sidewall and a frame-shaped outer sidewall that laterally surrounds the frame-shaped inner sidewall, and
the frame-shaped inner sidewall laterally surrounds the solder material portions.

11. The semiconductor structure of claim 10, wherein the frame-shaped inner sidewall and the frame-shaped outer sidewall have rounded corners in a plan view proximate to corner regions of the package.

12. The semiconductor structure of claim 1, wherein the at least one substrate trench comprises a plurality of L-shaped substrate trenches in a plan view proximate to corner regions of the package.

13. The semiconductor structure of claim 1, wherein the at least one substrate trench comprises a plurality of rectangular substrate trenches in a plan view located adjacent to corner regions of the package, wherein the plurality of rectangular substrate trenches have inner sidewalls that are parallel to proximal sidewalls of the package in a plan view.

14. A substrate package comprising:
a chip-side surface laminar circuit (SLC) comprising:
chip-side insulating layers;
chip-side wiring interconnects embedded within the chip-side insulating layers; and
chip-side bonding pads embedded within the chip-side insulating layers and electrically connected to the chip-side wiring interconnects;
a solder mask deposited over the chip-side insulating layers and top surfaces of the chip-side bonding pads; and
at least one substrate trench formed in the solder mask, wherein the at least one substrate trench has an inner sidewall located between an outer sidewall of the at least one substrate trench and proximal edges of the chip-side bonding pads.

15. The substrate package of claim 14, wherein the at least one substrate trench extends vertically through the solder mask and into the chip-side insulating layers, wherein the inner sidewall and the outer sidewall are in contact with sidewalls of the chip-side insulating layers and sidewalls of the solder mask.

16. The substrate package of claim 14, wherein the at least one substrate trench has a depth that is within a range of 10 microns to 100 microns.

17. A method of forming a semiconductor structure, comprising:
providing a package comprising at least one semiconductor die and a redistribution structure;
forming at least one substrate trench within a substrate package;
bonding the package to the substrate package such that the redistribution structure is bonded to the substrate package by solder material portions; and
applying an underfill material portion around the solder material portions and within the at least one substrate trench.

18. The method of claim 17, wherein forming the at least one substrate trench within the substrate package further comprises forming the at least one substrate trench within the substrate package by lithographically patterning a solder mask of the substrate package.

19. The method of claim 17, wherein forming the at least one substrate trench within the substrate package further comprises forming the at least one substrate trench within the substrate package by computer numerical control (CNC) machining chip-side insulating layers of the substrate package.

20. The method of claim 17, wherein forming the at least one substrate trench within the substrate package further comprises forming an inner wall and an outer wall of the at least one substrate trench, wherein a periphery of an area of the package is located between the inner wall and the outer wall of the at least one substrate trench in a plan view.
